(19) United States
(12) Patent Application Publication
(10) Pub. No.: US 2025/0311555 A1
(43) Pub. Date: Oct. 2, 2025

(54) DISPLAY APPARATUS AND METHOD OF MANUFACTURING DISPLAY APPARATUS

(71) Applicant: Samsung Display Co., Ltd., Yongin-Si (KR)

(72) Inventors: Hyuneok Shin, Yongin-si (KR); Juhyun Lee, Yongin-si (KR)

(21) Appl. No.: 19/021,161

(22) Filed: Jan. 15, 2025

(30) Foreign Application Priority Data
Mar. 27, 2024 (KR) 10-2024-0041988

(51) Int. Cl. H10K 59/122; H10K 59/12; H10K 59/80

(52) U.S. Cl. CPC H10K 59/122; H10K 59/1201; H10K 59/873

(57) ABSTRACT

Provided are a display apparatus and a method of manufacturing the display apparatus, the display apparatus including a plurality of light-emitting elements configured to emit light, an encapsulation layer covering the plurality of light-emitting elements, a bank unit disposed on the encapsulation layer and defining bank openings respectively above the plurality of light-emitting elements, a functional layer arranged in each of the bank openings. The bank unit is tapered to have an increasing width in a first direction away from the encapsulation layer and includes a wing portion protruding toward the functional layer.

### CROSS-REFERENCE TO RELATED APPLICATION

This application is based on and claims priority under 35 U.S.C. § 119 to Korean Patent Application No. 10-2024-0041988, filed on Mar. 27, 2024, in the Korean Intellectual Property Office, the disclosure of which is incorporated by reference herein in its entirety.

### BACKGROUND

### 1. Field

One or more embodiments relate to a display apparatus and a method of manufacturing the display apparatus, and more particularly, to a display apparatus with improved display quality, and a method of manufacturing the display apparatus.

### 2. Description of the Related Art

Recently, electronic devices have been widely used. Electronic devices are used in various ways, such as mobile electronic devices and fixed electronic devices, and these electronic devices include a display apparatus capable of providing a user with visual information, such as images or videos, to support various functions.

Recently, as various types of electronic devices, such as cell phones, personal digital assistants (PDA), computers, and large televisions (TV), have been developed, various types of display apparatuses applicable thereto have been developed. For example, display apparatuses widely used in the market include liquid-crystal display apparatuses including backlight units and organic light-emitting display apparatuses emitting different colors of light for each color region. Recently, display apparatuses including quantum dot color conversion layers (QD-CCL) have been developed. Quantum dots are excited by incident light and emit light having a longer wavelength than the incident light, and light in a low wavelength band is mainly used as the incident light. Recently, as the uses of display apparatuses have diversified, various designs have been proposed to improve the quality of the display apparatuses.

The above-mentioned background art is technical information that the inventor possesses for deriving the disclosure or obtains in the process of deriving the disclosure, and is not necessarily known technology disclosed to the general public prior to the filing of the disclosure.

### SUMMARY

One or more embodiments include a display apparatus with improved display quality by improving the brightness and light conversion efficiency while preventing color mixing between pixels.

However, these features are examples, and the scope of the disclosure is not limited thereto.

Additional aspects will be set forth in part in the description which follows and, in part, will be apparent from the description, or may be learned by practice of the presented embodiments of the disclosure.

According to one or more embodiments, a display apparatus includes a plurality of light-emitting elements configured to emit light, an encapsulation layer covering the plurality of light-emitting elements, a bank unit disposed on the encapsulation layer and defining bank openings respectively above the plurality of light-emitting elements, and a functional layer arranged in each of the bank openings. The bank unit is tapered to have an increasing width in a first direction away from the encapsulation layer and includes a wing portion protruding toward the functional layer.

In an embodiment, the bank unit may further include a first bank unit having a V-shape to have a groove having an increasing width in the first direction at a center of the first bank unit, and a second bank unit filling the groove of the first bank unit.

In an embodiment, the first bank unit may include a metal layer. The metal layer may include a flat portion on the encapsulation layer, inclined portions respectively arranged on sides of the flat portion and inclined from the flat portion to be farther away from each other in the first direction, and a protruding portion protruding from each of the inclined portions toward the functional layer.

In an embodiment, the first bank unit may further include a transparent coating layer disposed on each of upper and lower portions of the metal layer.

In an embodiment, the transparent coating layer may include indium tin oxide (ITO).

In an embodiment, the first bank unit may further include an insulating layer between the metal layer and the second bank unit.

In an embodiment, each of the inclined portions of the metal layer may have a thickness at a portion proximal to the flat portion greater than a thickness at a portion distal from the flat portion.

In an embodiment, the metal layer may include silver (Ag).

In an embodiment, the second bank unit may include a liquid-repellent material having liquid-repellent characteristics.

In an embodiment, the second bank unit may fill the groove and has a T-shape.

According to one or more embodiments, a method of manufacturing a display apparatus includes arranging an encapsulation layer to cover a plurality of light-emitting elements, disposing an organic layer on the encapsulation layer, forming a plurality of organic openings in the organic layer, arranging a plurality of layers including a metal layer to cover the plurality of organic openings and the organic layer, forming a bank unit defining a bank opening by etching layers stacked on an upper portion of the encapsulation layer in an area other than a photo area that is above the plurality of organic openings in a plan view, and arranging a functional layer in the bank opening.

In an embodiment, each of the plurality of organic openings may be tapered to have an increasing width in a first direction away from the encapsulation layer.

In an embodiment, the arranging of the plurality of layers may include arranging the metal layer in a V-shape along a shape of the tapered organic opening to provide a groove having an increasing width in the first direction from a center of the organic opening.

In an embodiment, the arranging of the plurality of layers may further include arranging a liquid-repellent layer to cover the metal layer and fill the groove.

In an embodiment, the forming of the bank unit may include etching the plurality of layers and arranging a liquid-repellent layer to fill the groove.

In an embodiment, a width of the photo area may be greater than a width of the organic opening, and the forming of the bank unit may include providing a wing portion protruding toward the bank opening.

In an embodiment, the arranging of the plurality of layers may further include arranging a transparent coating layer over and under the metal layer.

In an embodiment, the metal layer of the bank unit may include a flat portion on the encapsulation layer, inclined portions respectively arranged on sides of the flat portion and inclined from the flat portion to be farther away from each other in the first direction, and a protruding portion protruding from each of the inclined portions toward the bank opening.

In an embodiment, each of the inclined portions of the metal layer may have a thickness at a portion proximal to the flat portion greater than a thickness at a portion distal from the flat portion.

In an embodiment, the metal layer may include silver (Ag).

In one or more embodiments, an electronic apparatus may include one of the display apparatuses described above.

Other aspects, features, and advantages other than those described above will now become apparent from the following drawings, claims, and the detailed description of the disclosure.

### BRIEF DESCRIPTION OF THE DRAWINGS

The above and other aspects, features, and advantages of certain embodiments of the disclosure will be more apparent from the following description taken in conjunction with the accompanying drawings.

FIG. 1 is a schematic perspective view of a display apparatus according to an embodiment.

FIG. 2 is a schematic cross-sectional view of a display apparatus according to an embodiment.

FIG. 3 illustrates each of optical layers of a functional layer of FIG. 2.

FIG. 4 is an equivalent circuit diagram illustrating a light-emitting diode and a sub-pixel circuit electrically connected to the light-emitting diode included in a display apparatus according to an embodiment.

FIG. 5 is a schematic cross-sectional view of a display apparatus according to an embodiment.

FIG. 6 is a schematic cross-sectional view of a bank unit and a functional layer according to an embodiment and is an enlarged view of a region VI of FIG. 5.

FIGS. 7, 8, 9, 10, and 11 are schematic cross-sectional views illustrating some operations of a method of manufacturing a display apparatus according to an embodiment.

FIGS. 12, 13, 14, and 15 are schematic cross-sectional views illustrating some operations of a method of manufacturing a display apparatus according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. Effects and features of the disclosure and methods of achieving the same will be apparent with reference to embodiments and drawings described below in detail. The disclosure may, however, be embodied in many different forms and should not be construed as being limited to the embodiments set forth herein.

The disclosure will now be described more fully with reference to the accompanying drawings, in which embodiments of the disclosure are shown. Like reference numerals in the drawings denote like elements, and thus their description will not be repeated.

In the following embodiments, while such terms as “first,” “second,” etc., may be used to describe various elements, such elements must not be limited to the above terms.

In the following embodiments, an expression used in the singular encompasses the expression of the plural, unless it has a clearly different meaning in the context.

In the following embodiments, it is to be understood that the terms such as “including” and “having” are intended to indicate the existence of the features, or elements disclosed in the disclosure, and are not intended to preclude the possibility that one or more other features or elements may exist or may be added.

It will be understood that when a layer, region, or element is referred to as being formed on another layer, region, or element, it can be directly or indirectly formed on the other layer, region, or element. That is, for example, intervening layers, regions, or elements may be present.

Sizes of elements in the drawings may be exaggerated for convenience of explanation. In other words, since sizes and thicknesses of components in the drawings are arbitrarily illustrated for convenience of explanation, the following embodiments are not limited thereto.

The x, y, and z axes are not limited to three axes of an orthogonal coordinates system, and may be interpreted in a broad sense. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

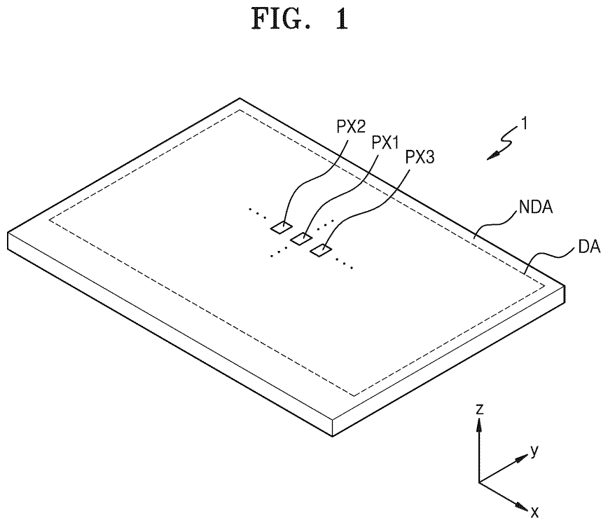

FIG. 1 is a schematic perspective view illustrating a display apparatus 1 according to an embodiment.

In one or more embodiments, an electronic apparatus may include the display apparatus described below. In other words, the display apparatus according to an embodiment may be implemented as an electronic apparatus such as a smartphone, a mobile phone, a navigation device, a game device, a television (TV), a vehicle head unit, a notebook computer, a laptop computer, a tablet computer, a personal media player (PMP), or a personal digital assistant (PDA). In an embodiment, the electronic apparatus may be a flexible apparatus.

Referring to FIG. 1, the display apparatus 1 may include a display area DA configured to implement an image and a non-display area NDA that does not implement an image. The display apparatus 1 may provide an image through an array of a plurality of sub-pixels, which are two-dimensionally arranged on an x-y plane in the display area DA. Each sub-pixel may emit a different color of light, for example, the sub-pixel may be one of a red sub-pixel, a green sub-pixel, and a blue sub-pixel.

In an embodiment, the plurality of sub-pixels may include a first sub-pixel PX1, a second sub-pixel PX2, and a third sub-pixel PX3, and hereinafter, for convenience of explanation, the case in which the first sub-pixel PX1 is a red sub-pixel, the second sub-pixel PX2 is a green sub-pixel, and the third sub-pixel PX3 is a blue sub-pixel is described.

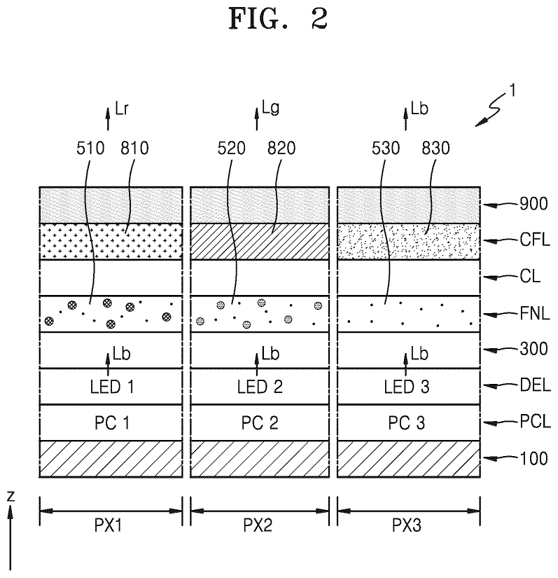

The first sub-pixel PX1, the second sub-pixel PX2, and the third sub-pixel PX3 are areas that may emit red light Lr, green light Lg, and blue light Lb (refer to FIG. 2), respectively, and the display apparatus 1 may provide an image by using light emitted by the sub-pixels.

The non-display area NDA is an area which does not provide an image, and may entirely surround the display area DA. A driver or a main voltage line, which is configured to provide electrical signals or power to pixel circuits, may be arranged in the non-display area NDA. A pad, which is an area to which an electronic device or a printed circuit board may be electrically connected, may be arranged in the non-display area NDA.

The display area DA may have a polygonal shape including a quadrangular shape, as shown in FIG. 1. For example, the display area DA may have a rectangular shape in which the horizontal length is greater than the vertical length, a rectangular shape in which the horizontal length is less than the vertical length, or a square shape. In an embodiment, the display area DA may have a circular shape, an oval shape, or a polygonal shape, such as a triangular shape or a pentagonal shape. In addition, the display apparatus 1 of FIG. 1 is illustrated as a flat panel display apparatus, but the display apparatus 1 may be implemented in various forms, such as a flexible, foldable, or rollable display apparatus, or the like.

In an embodiment, the display apparatus 1 may be an organic light-emitting display apparatus. In an embodiment, the display apparatus 1 may be an inorganic light-emitting display apparatus or a quantum dot light-emitting display apparatus. For example, an emission layer of a display element included in the display apparatus may include an organic material, an inorganic material, a quantum dot, an organic material and a quantum dot, an inorganic material and a quantum dot, or an organic material, an inorganic material, and a quantum dot. Hereinafter, for convenience of explanation, the case in which the display apparatus 1 is an organic light-emitting display apparatus is described in detail.

FIG. 2 is a schematic cross-sectional view of the display apparatus 1 according to an embodiment.

Referring to FIG. 2, the display apparatus 1 may include a circuit layer PCL on a substrate 100. The circuit layer PCL may include first to third sub-pixel circuits PC1, PC2, and PC3, and each of the first to third sub-pixel circuits PC1, PC2, and PC3 may include a transistor and/or a capacitor. A display element layer DEL may include, as display elements, first to third light-emitting elements, for example, first to third light-emitting diodes LED1, LED2, and LED3. The first to third sub-pixel circuits PC1, PC2, and PC3 may be electrically connected to the first to third light-emitting diodes LED1, LED2, and LED3 of the display element layer DEL, respectively.

Each of the first to third light-emitting diodes LED1, LED2, and LED3 may be an organic light-emitting diode including an organic material. In an embodiment, each of the first to third light-emitting diodes LED1, LED2, and LED3 may be an inorganic light-emitting diode including an inorganic material. The inorganic light-emitting display diode may include a PN junction diode including materials based on inorganic semiconductors. When a voltage is applied to the PN junction diode in a forward direction, holes and electrons may be injected, and energy generated by recombination of the holes and electrons may be converted into light energy to emit a certain color of light. The inorganic light-emitting diode described above may have a width of several to several hundred micrometers, or several to several hundred nanometers. In some embodiments, each of the first to third light-emitting diodes LED1, LED2, and LED3 may be a light-emitting diode including a quantum dot. As described above, an emission layer of each of the first to third light-emitting diodes LED1, LED2, and LED3 may include an organic material, an inorganic material, a quantum dot, an organic material and a quantum dot, or an inorganic material and a quantum dot.

The first to third light-emitting diodes LED1, LED2, and LED3 may emit the same color of light. For example, the first to third light-emitting diodes LED1, LED2, and LED3 may emit blue light Lb. However, the disclosure is not limited thereto. In an embodiment, the first to third light-emitting diodes LED1, LED2, and LED3 may emit different colors of light. Light (for example, the blue light Lb) emitted by the first to third light-emitting diodes LED1, LED2, and LED3 may pass through an encapsulation layer 300, which is on the display element layer DEL, and a functional layer FNL.

The functional layer FNL may include optical layers that transmit the light (for example, the blue light Lb) emitted by the display element layer DEL with or without converting the color of light. For example, the functional layer FNL may have quantum dot layers that convert the light (for example, the blue light Lb) emitted by the display element layer DEL into light of another color, and a transmissive layer that transmits the light (for example, the blue light Lb) emitted by the display element layer DEL without converting the color of light. The functional layer FNL may include a first quantum dot layer 510 corresponding to the first sub-pixel PX1, a second quantum dot layer 520 corresponding to the second sub-pixel PX2, and a transmissive layer 530 corresponding to the third sub-pixel PX3. The first quantum dot layer 510 may convert the blue light Lb into the red light Lr, and the second quantum dot layer 520 may convert the blue light Lb into the green light Lg. The transmissive layer 530 may transmit the blue light Lb without converting the color of light.

A color filter CFL may be disposed above the functional layer FNL. A capping layer CL may be arranged between the functional layer FNL and the color filter CFL. The color filter CFL may include first to third color filters 810, 820, and 830 having different colors. In an embodiment, the first color filter 810 may be a red color filter, the second color filter 820 may be a green color filter, and the third color filter 830 may be a blue color filter.

The color purity of the color-converted light and the transmitted light from the functional layer FNL may be improved while passing through the first to third color filters 810, 820, and 830. In addition, the color filter CFL may prevent or reduce external light (for example, light incident toward the display apparatus 1 from the outside of the display apparatus 1) from being reflected and visible to a user.

An overcoat layer 900 may be disposed on the color filter CFL. The overcoat layer 900 may include an organic material. For example, the overcoat layer 900 may include a transparent organic material, such as an acrylic resin. The overcoat layer 900 may serve as a buffer against external pressure or the like and may provide a flat upper surface.

In an embodiment, after the functional layer FNL, the capping layer CL, and the color filter CFL are sequentially formed on the encapsulation layer 300, the overcoat layer 900 may be formed by being directly applied on the color filter CFL and cured. In some embodiments, another optical film, for example, an anti-reflection (AR) film or the like, may be disposed on the overcoat layer 900. In addition, in some embodiments, a window (not shown) may be further disposed on the overcoat layer 900.

The display apparatus 1 having the structure described above may include an electronic device capable of displaying videos or still images, such as a television, a billboard, a movie theater screen, a monitor, a tablet personal computer (PC), a laptop, or the like.

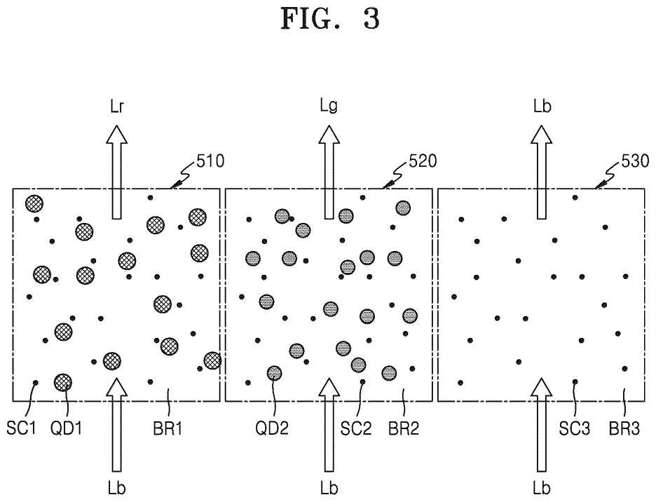

FIG. 3 illustrates each of the optical layers of the functional layer of FIG. 2.

Referring to FIG. 3, the first quantum dot layer 510 may convert the incident blue light Lb into the red light Lr. As shown in FIG. 3, the first quantum dot layer 510 may include a first photosensitive polymer BR1, first quantum dots QD1, and first scattering particles SC1, wherein the first quantum dots QD1 and the first scattering particles SC1 are dispersed in the first photosensitive polymer BR1.

The first quantum dots QD1 may be excited by the blue light Lb to isotropically emit the red light Lr having a greater wavelength than that of the blue light Lb. The first photosensitive polymer BR1 may be an organic material having light transmittance.

The first scattering particles SC1 may scatter the blue light Lb that is not absorbed by the first quantum dots QD1 to allow more first quantum dots QD1 to be excited, thereby increasing color conversion efficiency. The first scattering particles SC1 may be, for example, titanium oxide (TiO₂), metal particles, or the like. The first quantum dots QD1 may be selected from a Group II-VI compound, a Group III-V compound, a Group IV-VI compound, a Group IV element, a Group IV compound, and a combination thereof.

The second quantum dot layer 520 may convert the incident blue light Lb into the green light Lg. As shown in FIG. 3, the second quantum dot layer 520 may include a second photosensitive polymer BR2, second quantum dots QD2, and second scattering particles SC2, wherein the second quantum dots QD2 and the second scattering particles SC2 are dispersed in the second quantum dot layer 520.

The second quantum dots QD2 may be excited by the blue light Lb to isotropically emit the green light Lg having a greater wavelength than that of the blue light Lb. The second photosensitive polymer BR2 may be an organic material having light transmittance.

The second scattering particles SC2 may scatter the blue light Lb that is not absorbed by the second quantum dots QD2 to allow more second quantum dots QD2 to be excited, thereby increasing color conversion efficiency. The second scattering particles SC2, may be, for example, titanium oxide (TiO₂), metal particles, or the like. The second quantum dots QD2 may be selected from a Group II-VI compound, a Group III-V compound, a Group IV-VI compound, a Group IV element, a Group IV compound, and a combination thereof.

In some embodiments, the first quantum dots QD1 and the second quantum dots QD2 are the same material. In this case, the size of the second quantum dots QD2 may be greater than the size of the first quantum dots QD1.

The transmissive layer 530 may transmit the blue light Lb without converting the blue light Lb incident to the transmissive layer 530. As shown in FIG. 3, the transmissive layer 530 may include a third photosensitive polymer BR3 in which third scattering particles SC3 are dispersed. The third photosensitive polymer BR3 may be, for example, an organic material having light transmittance, such as a silicon resin, an epoxy resin, or the like, and may include the same material as the first photosensitive polymer BR1 and the second photosensitive polymer BR2. The third scattering particles SC3 may scatter and emit the blue light Lb, and may include the same material as the first scattering particles SC1 and the second scattering particles SC2.

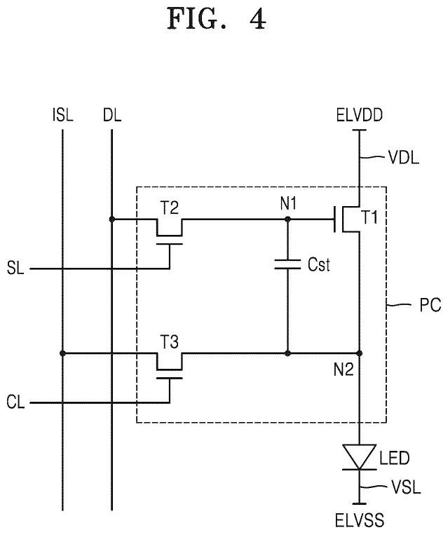

FIG. 4 is an equivalent circuit diagram illustrating a light-emitting diode LED and a sub-pixel circuit PC electrically connected to the light-emitting diode LED included in a display apparatus according to an embodiment. The sub-pixel circuit PC shown in FIG. 4 may correspond to each of the first to third sub-pixel circuits PC1, PC2, and PC3 described above with reference to FIG. 2, and a light-emitting diode LED of FIG. 4 may correspond to each of the first to third light-emitting diodes LED1, LED2, and LED3 described above with reference to FIG. 2.

Referring to FIG. 4, the light-emitting diode LED, for example, a sub-pixel electrode (e.g., an anode) of the light-emitting diode LED, may be connected to the sub-pixel circuit PC, and an opposite electrode (e.g., a cathode) of the light-emitting diode LED may be connected to a common voltage line VSL providing a common voltage ELVSS or an auxiliary line (not shown). The light-emitting diode LED may emit light with a brightness corresponding to an amount of current supplied from the sub-pixel circuit PC.

The sub-pixel circuit PC may control, in response to a data signal, the amount of current flowing from a driving voltage ELVDD to the common voltage line VSL via the light-emitting diode LED. The sub-pixel circuit PC may include a first transistor T1, a second transistor T2, a third transistor T3, and a storage capacitor Cst.

Each of the first transistor T1, the second transistor T2, and the third transistor T3 may be an oxide semiconductor transistor including a semiconductor layer including an oxide semiconductor, or a silicon semiconductor transistor including a semiconductor layer including polysilicon. According to the type of transistor, a first electrode of the transistor may be one of a source electrode and a drain electrode, and a second electrode of the transistor may be the other one of the source electrode and the drain electrode.

The first transistor T1 may be a driving transistor. A first electrode of the first transistor T1 may be connected to a driving voltage line VDL providing the driving voltage ELVDD, and a second electrode thereof may be connected to a sub-pixel electrode of the light-emitting diode LED. A gate electrode of the first transistor T1 may be connected to a first node N1. The first transistor T1 may control, in response to the voltage of the first node N1, the amount of current flowing from the driving voltage ELVDD to the light-emitting diode LED.

The second transistor T2 may be a switching transistor. A first electrode of the second transistor T2 may be connected to a data line DL, and a second electrode thereof may be connected to the first node N1. A gate electrode of the second transistor T2 may be connected to a scan line SL. The second transistor T2 may be turned on when a scan signal is supplied through the scan line SL to electrically connect the data line DL to the first node N1.

The third transistor T3 may be an initialization transistor and/or a sensing transistor. A first electrode of the third transistor T3 may be connected to a second node N2, and a second electrode thereof may be connected to a sensing line ISL. A gate electrode of the third transistor T3 may be connected to a control line CL.

The storage capacitor Cst may be connected between the first node N1 and the second node N2. For example, a first capacitor electrode of the storage capacitor Cst may be connected to the gate electrode of the first transistor T1, and a second capacitor electrode of the storage capacitor Cst may be connected to the sub-pixel electrode of the light-emitting diode LED.

Although FIG. 4 illustrates each of the first transistor T1, the second transistor T2, and the third transistor T3 as an N-channel metal-oxide-semiconductor (NMOS) transistor, the disclosure is not limited thereto. For example, at least one of the first transistor T1, the second transistor T2, and the third transistor T3 may be formed as a P-channel metal-oxide-semiconductor (PMOS) transistor.

FIG. 4 illustrates three transistors T1, T2, T3, but the disclosure is not limited thereto. The sub-pixel circuit PC may include four or more transistors.

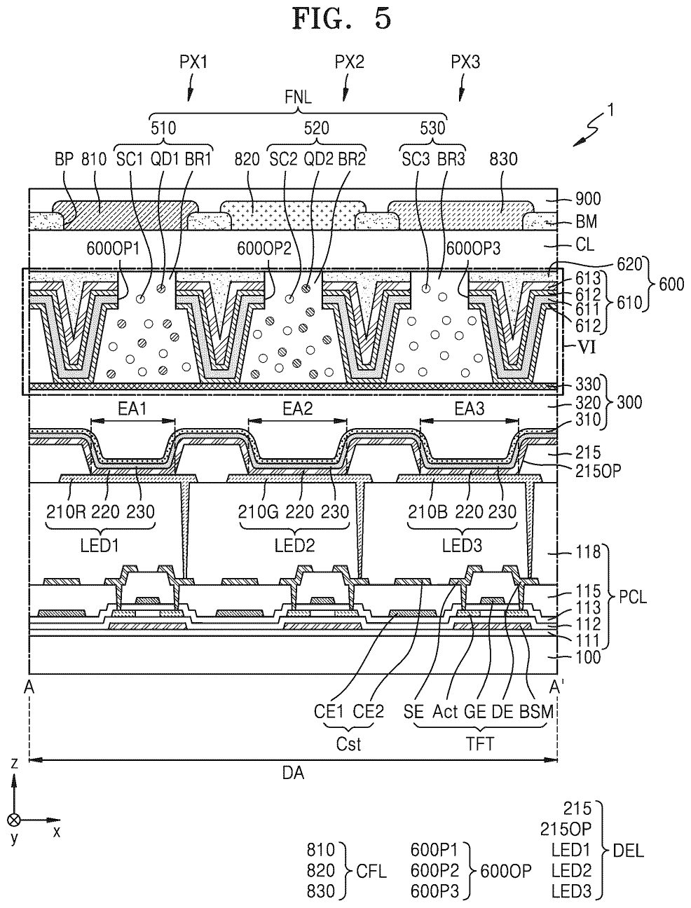

FIG. 5 is a schematic cross-sectional view of a display apparatus 1 according to an embodiment. Referring to FIG. 5, the display apparatus 1 may include the first sub-pixel PX1, the second sub-pixel PX2, and the third sub-pixel PX3, which emit different colors or light, and for example, the first sub-pixel PX1 may implement the red light Lr, the second sub-pixel PX2 may implement the green light Lg, and the third sub-pixel PX3 may implement the blue light Lb.

The display apparatus 1 may include a stacked structure of the substrate 100, the circuit layer PCL, the display element layer DEL, the functional layer FNL, and the color filter CFL, which are on the substrate 100. The display element layer DEL may include the first to third light-emitting diodes LED1, LED2, and LED3 respectively electrically connected to the sub-pixel circuits of the circuit layer PCL. The circuit layer PCL may include a plurality of sub-pixel circuits respectively corresponding to the first to third sub-pixels PX1, PX2, and PX3, and a sub-pixel circuit may include a plurality of transistors TFT and the storage capacitor Cst, as described above with reference to FIG. 4. For example, a transistor TFT may be the first transistor T1 (that is, the driving transistor, refer to FIG. 4).

The substrate 100 may include glass or a polymer resin. At this time, the polymer resin may include at least one of polyethersulfone, polyarylate, polyetherimide, polyethylene naphthalate, polyethylene terephthalate, polyphenylene sulfide, polyimide, polycarbonate, cellulose triacetate, cellulose acetate propionate, or the like. The substrate 100 may have a single-layered structure or a multi-layered structure, each including the material described above. In an embodiment, the substrate 100 may have a structure of organic material/inorganic material/organic material.

The circuit layer PCL may be disposed on the substrate 100. FIG. 5 illustrates that the circuit layer PCL includes the transistor TFT, the storage capacitor Cst, a first buffer layer 111, a second buffer layer 112, a gate insulating layer 113, an interlayer insulating layer 115, and a planarization layer 118, wherein the first buffer layer 111, the second buffer layer 112, the gate insulating layer 113, the interlayer insulating layer 115, and the planarization layer 118 are disposed below or/and above the components of the transistor TFT and the storage capacitor Cst.

The first buffer layer 111 and the second buffer layer 112 may reduce or block penetration of foreign materials, moisture, or external air from the lower portion of the substrate 100. Each of the first buffer layer 111 and the second buffer layer 112 may include an inorganic insulating material, such as silicon nitride, silicon oxynitride, and silicon oxide, and may include a single layer or a multi-layer, each including the inorganic insulating material described above.

A bias electrode BSM may be disposed on the first buffer layer 111 to correspond to the transistor TFT. In an embodiment, a voltage may be applied to the bias electrode BSM. In addition, the bias electrode BSM may prevent external light from reaching a semiconductor layer Act of the transistor TFT. Accordingly, characteristics of the transistor TFT may be stabilized. In some embodiments, the bias electrode BSM may be omitted.

The semiconductor layer Act may be disposed on the second buffer layer 112. The semiconductor layer Act may include amorphous silicon or polysilicon. In an embodiment, the semiconductor layer Act may include an oxide of at least one or more materials selected from a group consisting of indium (In), gallium (Ga), tin (Sn), zirconium (Zr), vanadium (V), hafnium (Hf), cadmium (Cd), germanium (Ge), chromium (Cr), titanium (Ti), aluminum (AI), cesium (Cs), cerium (Ce), and zinc (Zn). In some embodiments, the semiconductor layer Act may include a zinc-oxide-based material and may include Zn oxide, In—Zn oxide, Ga—In—Zn oxide, or the like. In some embodiments, the semiconductor layer Act may be an In—Ga—Zn—O (IGZO), In—Sn—Zn—O (ITZO), or In—Ga—Sn—Zn—O (IGTZO) semiconductor, which includes a metal such as In, Ga, and Sn in ZnO. The semiconductor layer Act may include a channel area, a source area, and a drain area, wherein the source area and the drain area are respectively arranged on both sides of the channel area. A gate electrode GE may overlap the channel area of the semiconductor layer Act.

The gate electrode GE may include a low-resistance metal material. The gate electrode GE may include a conductive material, such as molybdenum (Mo), aluminum (Al), copper (Cu), titanium (Ti), or the like, and may include a single layer or a multi-layer, each including the above material.

The gate insulating layer 113 may be arranged between the semiconductor layer Act and the gate electrode GE. The gate insulating layer 113 may include an inorganic insulating material, such as silicon oxide, silicon nitride, silicon oxynitride, aluminum oxide, titanium oxide, tantalum oxide, hafnium oxide, zinc oxide, or the like.

A first electrode CE1 of the storage capacitor Cst may be disposed on the same layer as the gate electrode GE. The first electrode CE1 may include the same material as the gate electrode GE. Although FIG. 5 illustrates that the gate electrode GE of the transistor TFT and the first electrode CE1 of the storage capacitor Cst are separately arranged, in an embodiment, the storage capacitor Cst may overlap the transistor TFT. In this case, the gate electrode GE of the transistor TFT may function as the first electrode CE1 of the storage capacitor Cst.

The interlayer insulating layer 115 may be provided to cover the gate electrode GE. The interlayer insulating layer 115 may include an inorganic insulating material, such as silicon oxide, silicon nitride, silicon oxynitride, aluminum oxide, titanium oxide, tantalum oxide, hafnium oxide, zinc oxide, or the like.

A second electrode CE2 of the storage capacitor Cst, a source electrode SE, and a drain electrode DE, or the like may be disposed on the upper portion of the interlayer insulating layer 115.

Each of the second electrode CE2 of the storage capacitor Cst, the source electrode SE, and the drain electrode DE may include a conductive material including Mo, Al, Cu, Ti, or the like, and may include a single layer or a multi-layer, each including the above material. For example, each of the second electrode CE2 of the storage capacitor Cst, the source electrode SE, and the drain electrode DE may have a multi-layered structure of Ti/Al/Ti. The source electrode SE and the drain electrode DE may be connected to the source area or the drain area of the semiconductor layer Act through a contact hole.

The second electrode CE2 of the storage capacitor Cst may overlap the first electrode CE1 with the interlayer insulating layer 115 therebetween to form the storage capacitor Cst. In this case, the interlayer insulating layer 115 may perform a function of a dielectric layer of the storage capacitor Cst.

The planarization layer 118 may be arranged to cover the second electrode CE2 of the storage capacitor Cst, the source electrode SE, and the drain electrode DE. The planarization layer 118 may include a single layer or a multi-layer, each including a film of an organic material, and may provide a flat upper surface. The planarization layer 118 may include benzocyclobutene (BCB), polyimide, hexamethyldisiloxane (HDMSO), a general commercial polymer such as poly (methyl methacrylate) (PMMA) or polystyrene (PS), a polymer derivative having a phenol group, an acrylic polymer, an imide polymer, an aryl ether polymer, an amide polymer, a fluorine polymer, a p-xylene polymer, a vinyl alcohol polymer, a mixture thereof, or the like.

The display element layer DEL may be disposed on the circuit layer PCL having the structure described above. The display element layer DEL may include, as display elements, the first to third light-emitting diodes LED1, LED2, and LED3, which are organic light-emitting diodes. The first light-emitting diode LED1, the second light-emitting diode LED2, and the third light-emitting diode LED3 may respectively include a first sub-pixel electrode 210R, a second sub-pixel electrode 210G, and a third sub-pixel electrode 210B. In an embodiment, the first light-emitting diode LED1, the second light-emitting diode LED2, and the third light-emitting diode LED3 may commonly include an emission layer 220 and an opposite electrode 230.

The first sub-pixel electrode 210R, the second sub-pixel electrode 210G, and the third sub-pixel electrode 210B may be a (semi) transparent electrode or a reflective electrode. In some embodiments, each of the first sub-pixel electrode 210R, the second sub-pixel electrode 210G, and the third sub-pixel electrode 210B may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). In an embodiment, each of the first sub-pixel electrode 210R, the second sub-pixel electrode 210G, and the third sub-pixel electrode 210B may include a reflective film including silver (Ag), magnesium (Mg), Al, platinum (Pt), palladium (Pd), gold (Au), nickel (Ni), neodymium (Nd), iridium (Ir), chromium (Cr), or compounds thereof. In an embodiment, each of the first sub-pixel electrode 210R, the second sub-pixel electrode 210G, and the third sub-pixel electrode 210B may further include a film including ITO, IZO, ZnO, or In₂O₃ above/below the reflective film described above. For example, each of the first sub-pixel electrode 210R, the second sub-pixel electrode 210G, and the third sub-pixel electrode 210B may be provided as ITO/Ag/ITO.

A pixel defining layer 215 may be disposed on the planarization layer 118. The pixel defining layer 215 may include openings 215OP extending to and exposing the central portion of each of the first sub-pixel electrode 210R, the second sub-pixel electrode 210G, and the third sub-pixel electrode 210B. The pixel defining layer 215 may cover the edge of each of the first sub-pixel electrode 210R, the second sub-pixel electrode 210G, and the third sub-pixel electrode 210B. The pixel defining layer 215 may prevent an arc or the like from being generated at the edges of the first sub-pixel electrode 210R, the second sub-pixel electrode 210G, and the third sub-pixel electrode 210B by increasing the distance between the edges of the first sub-pixel electrode 210R, the second sub-pixel electrode 210G, and the third sub-pixel electrode 210B and the opposite electrode 230 on the upper portion of the first sub-pixel electrode 210R, the second sub-pixel electrode 210G, and the third sub-pixel electrode 210B.

The pixel defining layer 215 may include one or more organic insulating materials selected from a group consisting of polyimide, polyamide, an acrylic resin, BCB, and a phenol resin.

The emission layer 220 of each of the first light-emitting diode LED1, the second light-emitting diode LED2, and the third light-emitting diode LED3 may include an organic material including a fluorescent or phosphorescent material that emits red, green, blue, or white light. The emission layer 220 may include a low-molecular-weight organic material or a polymer organic material, and a functional layer, such as a hole transport layer (HTL), a hole injection layer (HIL), an electron transport layer (ETL), an electron injection layer (EIL), or the like, may be further selectively disposed below and above the emission layer 220. As shown in FIG. 5, the emission layer 220 may be integrally formed across the first sub-pixel electrode 210R, the second sub-pixel electrode 210G, and the third sub-pixel electrode 210B, but the disclosure is not limited thereto. In some embodiments, the emission layer 220 may also include a layer patterned to correspond to each of the first sub-pixel electrode 210R, the second sub-pixel electrode 210G, and the third sub-pixel electrode 210B. In any case, the emission layer 220 may be a first-color emission layer. The first-color emission layer may emit light in a first wavelength band, for example, blue light. In an embodiment, the emission layer 220 may emit light having a wavelength of about 450 nm to about 495 nm.

The opposite electrode 230 may be disposed on the emission layer 220 and may be arranged to correspond to the first sub-pixel electrode 210R, the second sub-pixel electrode 210G, and the third sub-pixel electrode 210B. The opposite electrode 230 may be integrally formed across the first sub-pixel electrode 210R, the second sub-pixel electrode 210G, and the third sub-pixel electrode 210B. In an embodiment, the opposite electrode 230 may include a conductive material having a low work function. For example, the opposite electrode 230 may include a (semi) transparent layer, the (semi) transparent layer including Ag, Mg, Al, Pt, Pd, Au, Ni, Nd, Ir, Cr, lithium (Li), calcium (Ca), alloys thereof, or the like. In an embodiment, the opposite electrode 230 may further include a layer, such as ITO, IZO, ZnO, or In₂O₃, above the (semi) transparent layer including the materials stated above.

First to third emission areas EA1, EA2, and EA3 may respectively correspond to the first to third sub-pixels PX1, PX2, and PX3. The first to third emission areas EA1, EA2, and EA3 may be areas where light generated by the first to third light-emitting diodes LED1, LED2, and LED3 is emitted to the outside, respectively. The first emission area EA1 may be defined as a portion of the first sub-pixel electrode 210R, which is exposed by the opening 215OP of the pixel defining layer 215. The second emission area EA2 may be defined as a portion of the second sub-pixel electrode 210G, which is exposed by the opening 215OP of the pixel defining layer 215. The third emission area EA3 may be defined as a portion of the third sub-pixel electrode 210B, which is exposed by the opening 215OP of the pixel defining layer 215. In other words, the first emission area EA1, the second emission area EA2, and the third emission area EA3 may be respectively defined by the openings 215OP of the pixel defining layer 215.

The first emission area EA1, the second emission area EA2, and the third emission area EA3 may be spaced apart from each other. An area of the display area DA other than the first emission area EA1, the second emission area EA2, and the third emission area EA3 may be a non-emission area. The first emission area EA1, the second emission area EA2, and the third emission area EA3 may be distinguished by the non-emission area.

A spacer (not shown) may be further included on the pixel defining layer 215 to prevent mask imprinting. In an embodiment, the spacer may be integrally formed with the pixel defining layer 215. For example, the spacer and the pixel defining layer 215 may be simultaneously formed in the same process by using a halftone mask process.

The encapsulation layer 300 may be arranged to cover the display element layer DEL. Because the first light-emitting diode LED1, the second light-emitting diode LED2, and the third light-emitting diode LED3 are easily damaged by moisture or oxygen introduced from the outside, the first light-emitting diode LED1, the second light-emitting diode LED2, and the third light-emitting diode LED3 may be protected by being covered with the encapsulation layer 300. The encapsulation layer 300 may cover the display area DA and extend to the outside of the display area DA. The encapsulation layer 300 may include at least one organic encapsulation layer and at least one inorganic encapsulation layer. For example, the encapsulation layer 300 may include a first inorganic encapsulation layer 310, a first organic encapsulation layer 320, and a second inorganic encapsulation layer 330, which are sequentially stacked.

Each of the first inorganic encapsulation layer 310 and the second inorganic encapsulation layer 330 may include at least one inorganic material from among aluminum oxide, titanium oxide, tantalum oxide, hafnium oxide, zinc oxide, silicon oxide, silicon nitride, and silicon oxynitride. The first organic encapsulation layer 320 may include a polymer-based material. The polymer-based material may include an acrylic resin, an epoxy resin, polyimide, polyethylene, or the like. In an embodiment, the first organic encapsulation layer 320 may include acrylate. The first organic encapsulation layer 320 may be formed by curing a monomer or applying a polymer.

As the encapsulation layer 300 includes the multi-layered structure described above, even when cracks occur in the encapsulation layer 300, the encapsulation layer 300 may prevent the cracks from propagating between the first inorganic encapsulation layer 310 and the first organic encapsulation layer 320 or between the first organic encapsulation layer 320 and the second inorganic encapsulation layer 330. The formation of a path, through which external moisture or oxygen, or the like penetrates into the display area DA, may be prevented or reduced.

In some embodiments, other layers, such as a capping layer or the like, may be further arranged between the first inorganic encapsulation layer 310 and the opposite electrode 230.

In addition, in an embodiment, the first organic encapsulation layer 320 may include a blue pigment or blue dye. The first organic encapsulation layer 320 may transmit only light having a preset wavelength and absorb light having other wavelengths. In an embodiment, the first organic encapsulation layer 320 may transmit only blue light, for example, only light having a wavelength of about 450 nm to about 495 nm.

Accordingly, the first organic encapsulation layer 320 may absorb a portion of light transmitting through the color filter CFL among external light incident toward the display apparatus 1 or a portion of light reflected by the opposite electrode 230 and/or the first to third sub-pixel electrodes 210R, 210G, and 210B below the color filter CFL. The first organic encapsulation layer 320 may reduce a portion of the reflected light from reaching the functional layer FNL, for example, the first quantum dot layer 510 and the second quantum dot layer 520. Accordingly, emission reflection of the first quantum dot layer 510 and the second quantum dot layer 520 due to external light or internal reflected light may be reduced, and undesired colors may be prevented from implementing. In addition, the color purity and brightness of the display apparatus 1 may be improved.

In addition, when the first organic encapsulation layer 320 includes a blue pigment or blue dye, it may have an effect equivalent to a color filter without adding a separate process to form a color filter, and thus the economic advantages to the process are included. However, the disclosure is not limited thereto, and a separate color filter may be disposed on the upper portion of the encapsulation layer 300.

A bank unit 600 may be disposed on the encapsulation layer 300. The bank unit 600 may include an organic material or an inorganic material. For example, the bank unit 600 may include an inorganic material, such as silicon oxide, silicon nitride, and/or silicon oxynitride, or the like. In some cases, the bank unit 600 may include a light-blocking material to function as a light-blocking layer. The light-blocking material may include, for example, at least one of black pigment, black dye, black particles, or metal particles.

The bank unit 600 may define bank openings 600OP. A first bank opening 600OP1 of the bank unit 600 may be above and correspond to the opening 215OP exposing the first sub-pixel electrode 210R of the pixel defining layer 215, a second bank opening 600OP2 of the bank unit 600 may be above and correspond to the opening 215OP exposing the second sub-pixel electrode 210G of the pixel defining layer 215, and a third bank opening 600OP3 of the bank unit 600 may be above and correspond to the opening 215OP exposing the third sub-pixel electrode 210B of the pixel defining layer 215. That is, when viewed from a direction (z axis direction) perpendicular to the substrate 100, the first bank opening 600OP1 of the bank unit 600 may overlap the opening 215OP exposing the first sub-pixel electrode 210R of the pixel defining layer 215, the second bank opening 600OP2 of the bank unit 600 may overlap the opening 215OP exposing the second sub-pixel electrode 210G of the pixel defining layer 215, and the third bank opening 600OP3 of the bank unit 600 may overlap the opening 215OP exposing the third sub-pixel electrode 210B of the pixel defining layer 215.

The bank openings 600OP of the bank unit 600 may be filled with the functional layer FNL. In an embodiment, the functional layer FNL may include at least one of a quantum dot and a scattering particle. The functional layer FNL may include the first quantum dot layer 510, the second quantum dot layer 520, and the transmissive layer 530.

The first bank opening 600OP1 of the bank unit 600 may be filled with the first quantum dot layer 510. The first quantum dot layer 510 may be above and overlap the first emission area EA1. The first sub-pixel PX1 may include the first light-emitting diode LED1 and the first quantum dot layer 510.

The first quantum dot layer 510 may convert light in a first wavelength band generated by the emission layer 220 on the first sub-pixel electrode 210R into light in a second wavelength band. The first quantum dot layer 510 may convert blue light into red light. For example, when light having a wavelength of about 450 nm to about 495 nm is generated by the emission layer 220 on the first sub-pixel electrode 210R, the first quantum dot layer 510 may convert the light into light having a wavelength of about 630 nm to about 780 nm. Accordingly, the light having the wavelength of about 630 nm to about 780 nm may be emitted from the first sub-pixel PX1 to the outside.

The first quantum dot layer 510 may include the first photosensitive polymer BR1, the first quantum dots QD1, and the first scattering particles SC1, wherein the first quantum dots QD1 and the first scattering particles SC1 are dispersed in the first photosensitive polymer BR1.

The second bank opening 600OP2 of the bank unit 600 may be filled with the second quantum dot layer 520. The second quantum dot layer 520 may be above and overlap the second emission area EA2. The second sub-pixel PX2 may include the second light-emitting diode LED2 and the second quantum dot layer 520.

The second quantum dot layer 520 may convert light in a first wavelength band generated by the emission layer 220 on the second sub-pixel electrode 210G into light in a third wavelength band. The second quantum dot layer 520 may convert blue light into green light. For example, when light having a wavelength of about 450 nm to about 495 nm is generated by the emission layer 220 on the second sub-pixel electrode 210G, the second quantum dot layer 520 may convert the light into light having a wavelength of about 495 nm to about 570 nm. Accordingly, the light having the wavelength of about 495 nm to about 570 nm may be emitted from the second sub-pixel PX2 to the outside.

The second quantum dot layer 520 may include the second photosensitive polymer BR2, the second quantum dots QD2, and the second scattering particles SC2, wherein the second quantum dots QD2 and the second scattering particles SC2 are dispersed in the second photosensitive polymer BR2.

The third bank opening 600OP3 of the bank unit 600 may be filled with the transmissive layer 530. The transmissive layer 530 may be above and overlap the third emission area EA3. The third sub-pixel PX3 may include the third light-emitting diode LED3 and the transmissive layer 530.

The transmissive layer 530 may emit light generated by the emission layer 220 on the third sub-pixel electrode 210B to the outside without converting the wavelength of the light. The transmissive layer 530 may transmit blue light without converting the color of light. For example, when light having a wavelength of about 450 nm to about 495 nm is generated by the emission layer 220 on the third sub-pixel electrode 210B, the transmissive layer 530 may emit the light to the outside without converting the wavelength of light.

The transmissive layer 530 may include the third photosensitive polymer BR3 in which the third scattering particles SC3 are dispersed. In an embodiment, the transmissive layer 530 may not include a quantum dot.

At least one of the first quantum dot QD1 and the second quantum dot QD2 may include a semiconductor material, such as cadmium sulfide (CdS), cadmium telluride (CdTe), zinc sulfide (ZnS), or indium phosphide (InP). The size of the quantum dot may be several nanometers, and the wavelength of light after conversion may be changed according to the size of the quantum dot.

In an embodiment, the core of the quantum dot may be selected from a Group II-VI compound, a Group III-V compound, a Group IV-VI compound, a Group IV element, a Group IV compound, and a combination thereof.

The Group II-VI compound may be selected from a group including a binary compound, a ternary compound, and a quaternary compound, the binary compound being selected from a group including CdSe, CdTe, ZnS, ZnSe, ZnTe, ZnO, HgS, HgSe, HgTe, MgSe, MgS, and a mixture thereof; the ternary compound being selected from a group including AgInS, CulnS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; the quaternary compound being selected from a group including HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The Group III-V compounds may be selected from a group including a binary compound, a ternary compound, and a quaternary compound, the binary compound being selected from a group including GaN, GaP, GaAs, GaSb, AlN, AlP, AlAs, AlSb, InN, InP, InAs, InSb, and a mixture thereof; the ternary compound being selected from a group including GaNP, GaNAs, GaNSb, GaPAs, GaPSb, AlNP, AlNAs, AlNSb, AIPAs, AIPSb, InGaP, InNP, InNAs, InNSb, InPAs, InPSb, GaAlNP, and a mixture thereof, the quaternary compound being selected from a group including GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof.

The Group IV-VI compounds may be selected from a group including a binary compound, a ternary compound, and a quaternary compound, the binary compound being selected from a group including SnS, SnSe, SnTe, PbS, PbSe, PbTe, and a mixture thereof; the ternary compound being selected from a group including SnSeS, SnSeTe, SnSTe, PbSeS, PbSeTe, PbSTe, SnPbS, SnPbSe, SnPbTe, and a mixture thereof; the quaternary compound being selected from a group including SnPbSSe, SnPbSeTe, SnPbSTe, and a mixture thereof. The Group IV element may be selected from a group including Si, Ge, and a mixture thereof. The Group IV compound may be a binary compound selected from a group including SiC, SiGe, and a mixture thereof.

The binary compound, the ternary compound, and the quaternary compound may be present in the particles at a uniform concentration, or may be present in the same particle by being partially divided into different concentrations. In addition, one quantum dot may have a core/shell structure surrounding another quantum dot. An interface between the core and the shell may have a concentration gradient where a concentration of elements in the shell decreases toward the center of the interface.

In some embodiments, the quantum dot may have a core-shell structure including the core described above and a shell surrounding the core. The shell of the quantum dot may function as a protective layer preventing chemical modification of the core to maintain semiconductor characteristics and/or may function as a charging layer for imparting electrophoretic characteristics to the quantum dot. The shell may include a single layer or a multi-layer. An interface between the core and the shell may have a concentration gradient where a concentration of elements in the shell decreases toward the center of the interface. Examples of the shell of the quantum dot may include an oxide of a metal or a nonmetal, a semiconductor compound, or a combination thereof.

For example, the oxide of the metal or the nonmetal may include a binary compound such as SiO₂, Al₂O₃, TiO², ZnO, MnO, Mn₂O₃, Mn₃O₄, CuO, FeO, Fe₂O₃, Fe₃O₄, CoO, Co₃O₄, NiO, or the like, or a ternary compound such as MgAl₂O₄, CoFe₂O₄, NiFe₂O₄, CoMn₂O₄, or the like, but the disclosure is not limited thereto.

In addition, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or the like, but the disclosure is not limited thereto.

In an embodiment, the quantum dot may have a full width of half maximum (FWHM) of an emission wavelength spectrum of about 45 nm or less, suitably about 40 nm or less, and more suitably about 30 nm or less. Color purity and color reproducibility may be improved in the above range. In addition, as light emitted through the quantum dot is emitted in all directions, a viewing angle of light may be improved.

In addition, a form of the quantum dot may be a form that is generally used in the art and is not particularly limited, and more particularly, the form of the quantum dot may include a sphere shape, a pyramid shape, a multi-arm shape, or cubic nanoparticles, nanotubes, nanowires, nanofibers, nanoplatelets, or the like.

The quantum dot may control the color of light emitted according to the particle size of the quantum dot, and accordingly, the quantum dot may have various emission colors such as blue, red, green, or the like.

The first scattering particles SC1, the second scattering particles SC2, and the third scattering particles SC3 may scatter light so that more light may be emitted. The first scattering particles SC1, the second scattering particles SC2, and the third scattering particles SC3 may increase light output efficiency. At least one of the first scattering particles SC1, the second scattering particles SC2, and the third scattering particles SC3 may include any material from among metal or metal oxide to evenly scatter light. For example, at least one of the first scattering particles SC1, the second scattering particles SC2, and the third scattering particles SC3 may include at least one of TiO₂, ZrO₂, Al₂O₃, In₂O₃, ZnO, SnO₂, Sb₂O₃, and ITO. In addition, at least one of the first scattering particles SC1, the second scattering particles SC2, and the third scattering particles SC3 may have a refractive index of 1.5 or more. Accordingly, the light output efficiency of the functional layer FNL may be improved. In some embodiments, at least one of the first scattering particles SC1, the second scattering particles SC2, and the third scattering particles SC3 may be omitted.

Each of the first photosensitive polymer BR1, the second photosensitive polymer BR2, and the third photosensitive polymer BR3 may include a transparent organic material. For example, at least one of the first photosensitive polymer BR1, the second photosensitive polymer BR2, and the third photosensitive polymer BR3 may include a polymer resin, such as acrylic, BCB, or HMDSO.

The capping layer CL may be disposed on the bank unit 600 and the functional layer FNL. The capping layer CL may prevent or reduce impurities such as moisture and/or air from penetrating from the outside to damage or contaminate the functional layer FNL, and may prevent cracks from occurring and propagating due to external forces. The capping layer CL may improve reliability of the display apparatus 1 by strengthening the protection of the functional layer FNL in the display apparatus 1 which does not include an upper substrate and has a structure in which components are stacked on a single substrate 100.

The capping layer CL may cover the display area DA and extend to the outside of the display area DA. The capping layer CL may include an inorganic insulating material, such as silicon nitride, silicon oxide, or silicon oxynitride. The capping layer CL and the encapsulation layer 300 may be arranged so that the functional layer FNL, for example, the first quantum dot layer 510, the second quantum dot layer 520, and the transmissive layer 530, is arranged between the capping layer CL and the encapsulation layer 300. The first quantum dot layer 510 and the second quantum dot layer 520 may include the quantum dots as described above, and the quantum dots include nanoparticles, and thus the quantum dots may react with moisture, oxygen, or the like and deteriorate. Accordingly, the capping layer CL and the encapsulation layer 300 may be disposed on the upper and lower portions of the first quantum dot layer 510 and the second quantum dot layer 520 to cover the first quantum dot layer 510 and the second quantum dot layer 520 such that moisture, oxygen, or the like may be prevented from being introduced to the quantum dots inside the first quantum dot layer 510 and the second quantum dot layer 520.

The color filter CFL may be disposed on the upper portion of the capping layer CL. In an embodiment, the color filter CFL may be directly formed on the upper surface (in a z axis direction) of the capping layer CL, and may include the first color filter 810, the second color filter 820, and the third color filter 830. The first color filter 810 may be disposed on the upper portion of the first quantum dot layer 510 to correspond to the first sub-pixel PX1, the second color filter 820 may be disposed on the upper portion of the second quantum dot layer 520 to correspond to the second sub-pixel PX2, and the third color filter 830 may be disposed on the upper portion of the transmissive layer 530 to correspond to the third sub-pixel PX3. Each of the first to third color filters 810, 820, and 830 may include a photosensitive resin. In addition, the first to third color filters 810, 820, and 830 may include pigments or dyes that exhibit unique colors, respectively.

The first color filter 810 may be a red color filter. For example, the first color filter 810 may only allow light having a wavelength of about 630 nm to about 780 to pass through. The first color filter 810 may include a red pigment or dye. The second color filter 820 may be a green color filter. For example, the second color filter 820 may only allow light having a wavelength of about 495 nm to about 570 nm to pass through. The second color filter 820 may include a green pigment or dye. The third color filter 830 may be a blue color filter. For example, the third color filter 830 may only allow light having a wavelength of about 450 nm to about 495 nm to pass through. The third color filter 830 may include a blue pigment or dye.

The color filter CFL may reduce external light reflection of the display apparatus 1. For example, when external light reaches the first color filter 810, as described above, only light having a preset wavelength may pass through the first color filter 810, and light having other wavelengths may be absorbed by the first color filter 810. Accordingly, only light having the preset wavelength among the external light incident to the display apparatus 1 may pass through the first color filter 810, and a portion of the light passing through the first color filter 810 may be reflected by the opposite electrode 230 and/or the first sub-pixel electrode 210R on the lower portion of the first color filter 810 and may be emitted to the outside again. Because only a portion of external light incident on a place where the first sub-pixel PX1 is located is reflected to the outside, the first color filter 810 may reduce the external light reflection. The above descriptions may also be applied to the second color filter 820 and the third color filter 830.

In an embodiment, the color filter CFL may be arranged between a light-blocking layer BM, e.g., in openings BP of the light blocking layer BM. The light-blocking layer BM may be disposed on the capping layer CL and may be arranged to overlap the bank unit 600 in a plan view. The light-blocking layer BM may include a light-blocking material. The light-blocking material may include an opaque inorganic insulating material including a metal oxide such as titanium oxide (TiO₂), chromium oxide (Cr₂O₃), or molybdenum oxide (MoO₃), or an opaque organic insulating material such as a black resin or the like. The light-blocking layer BM may prevent light leakage from occurring in the display apparatus 1 by blocking light from being emitted to the outside to areas other than emission areas.

The overcoat layer 900 may be arranged to cover the color filter CFL. The overcoat layer 900 may be an organic layer including an organic material. For example, the overcoat layer 900 may include a colorless transparent organic material, such as an acrylic resin. The overcoat layer 900 may protect the color filter CFL and planarize the upper surface of the color filter CFL. The lower surface of the overcoat layer 900 may have a concavo-convex structure due to the stacked structure of the first to third color filters 810, 820, and 830 of the color filter CFL. The upper surface of the overcoat layer 900 may be a flat surface. In some embodiments, another layer, such as a capping layer or the like, may be further disposed on the upper portion of the overcoat layer 900 and/or between the overcoat layer 900 and the color filter CFL. The capping layer may include an inorganic material. In some embodiments, the overcoat layer 900 may be covered with a window (not shown).

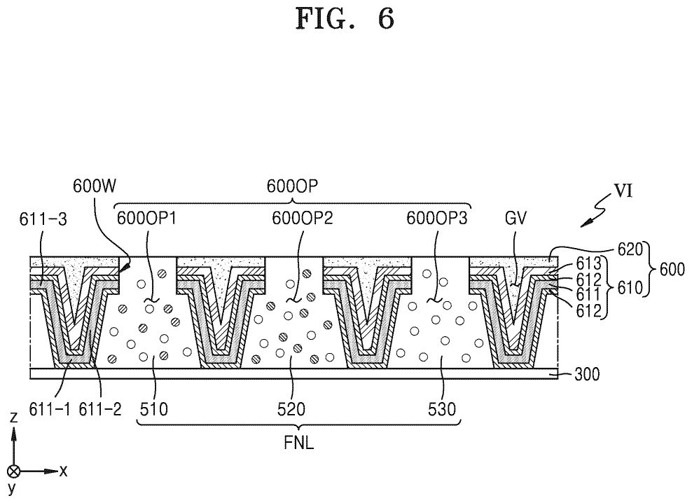

FIG. 6 is a schematic cross-sectional view of the bank unit 600 and the functional layer FNL according to an embodiment and is an enlarged view of a region VI of FIG. 5.

Referring to FIG. 6, the bank unit 600 may be disposed on the encapsulation layer 300 and define the bank openings 600OP. The bank openings 600OP may be arranged to be above and overlap the light-emitting diode LED, for example, the first to third light-emitting diodes LED1, LED2, and LED3, respectively. In particular, the first bank opening 600OP1 of the bank unit 600 may be above and correspond to the opening 215OP exposing the first sub-pixel electrode 210R of the pixel defining layer 215, the second bank opening 600OP2 of the bank unit 600 may be above and correspond to the opening 215OP exposing the second sub-pixel electrode 210G of the pixel defining layer 215, and the third bank opening 600OP3 of the bank unit 600 may be above and correspond to the opening 215OP exposing the third sub-pixel electrode 210B of the pixel defining layer 215. That is, when viewed from a direction (z axis direction) perpendicular to the substrate 100, the first bank opening 600OP1 of the bank unit 600 may overlap the opening 215OP exposing the first sub-pixel electrode 210R of the pixel defining layer 215, the second bank opening 600OP2 of the bank unit 600 may overlap the opening 215OP exposing the second sub-pixel electrode 210G of the pixel defining layer 215, and the third bank opening 600OP3 of the bank unit 600 may overlap the opening 215OP exposing the third sub-pixel electrode 210B of the pixel defining layer 215.

At this time, the bank unit 600 may function as a partition wall defining the bank openings 600OP, and in other words, the bank unit 600 may be arranged between the bank openings 600OP. In an embodiment, the bank unit 600 may have an inverted trapezoidal shape in a cross section taken in a direction perpendicular to a display surface (e.g., an xy plane) that displays an image and/or a plane (e.g., the xy plane) of the encapsulation layer 300. That is, in the cross section, the bank unit 600 may be tapered to have a wider width in a direction away from the encapsulation layer 300, for example, in a direction (a +z direction of FIG. 6) toward the color filter CFL from the encapsulation layer 300. Accordingly, the bank opening 600OP may have a normal trapezoidal shape. That is, the bank opening 600OP may be a tapered opening having a decreasing width in a direction away from the encapsulation layer 300, for example, in the direction toward the color filter CFL from the encapsulation layer 300.

In addition, in an embodiment, the bank unit 600 may include a wing portion 600W. The wing portion 600W may be formed on the upper portion of the bank unit 600 having an inverted trapezoidal shape to protrude from both side surfaces of the bank unit 600. In particular, each wing portion 600W may protrude toward the bank opening 600OP and/or the functional layer FNL accommodated within the bank opening 600OP from each of both inclined side surfaces of the bank unit 600 having an inverted trapezoidal shape.

In this case, the bank opening 600OP may include a lower opening and an upper opening. The lower opening may be an opening defined by the bank unit 600 having an inverted trapezoidal tapered shape. The upper opening may be an opening defined by the wing portion 600W. In an embodiment, the width of the lower opening may reduce toward the top, that is, a direction (the +z direction of FIG. 6) toward the color filter CFL from the encapsulation layer 300. At this time, the slope of the reducing width may be constant. In addition, in an embodiment, the width of the upper opening may be constant. At this time, the minimum width the lower opening may be greater than the width of the upper opening. In addition, the upper opening may be formed to offset inward from the top of the lower opening toward the center of the bank opening.

The bank unit 600 may include a first bank unit 610 and a second bank unit 620. The first bank unit 610 is a layer including a metal layer 611 and may form the lower portion of the bank unit 600. In an embodiment, the first bank unit 610 may have an approximately V-shape, and thus the first bank unit 610 may include a groove GV at the center thereof. The groove GV may have an increasing width in a direction from the encapsulation layer 300 toward the color filter CFL.

In an embodiment, the metal layer 611 may include a flat portion 611-1, an inclined portion 611-2, and a protruding portion 611-3. The flat portion 611-1 may be a flat portion on the encapsulation layer 300. The inclined portion 611-2 may be arranged on each of opposite sides of the flat portion 611-1, and the inclined portions 611-2 may be tapered to become farther away from each other in a direction toward the color filter CFL from the encapsulation layer 300. Accordingly, it may be said that the metal layer 611 has an approximately V-shape. The protruding portion 611-3 may protrude toward the outside from each of the inclined portions 611-2, that is, toward the functional layer FNL accommodated in the bank opening 600OP. Because the metal layer 611 has an approximately V-shape, the metal layer 611 may have the groove GV in the center thereof.

In an embodiment, the metal layer 611 may have a constant thickness, but the disclosure is not limited thereto. In an embodiment, the thickness of the inclined portion 611-2 of the metal layer 611 may be greater at a portion proximal (near) the flat portion 611-1 than the thickness at a portion distal (away from) from the flat portion 611-1. This may be because the metal layer 611 is formed by being stacked on an organic layer, as will be described below.

In an embodiment, the metal layer 611 may include Ag. Ag particles have excellent reflectivity, so light that reaches the metal layer 611 may be reflected from the surface of the metal layer 611. Accordingly, light incident on the first quantum dot layer 510, the second quantum dot layer 520, and the transmissive layer 530 may be scattered on the surface of the metal layer 611 and proceed through various paths. Accordingly, the incident light may be converted into more colors or scattered within the first quantum dot layer 510, the second quantum dot layer 520, and the transmissive layer 530, and thus light conversion efficiency may be improved. In addition, because the metal layer 611 reflects light that reaches the metal layer 611 from the surface of the metal layer 611, absorption of incident light by other portions of the bank unit 600 may be reduced, and light extraction efficiency and brightness may be improved. In addition, Ag particles resonate strongly with visible light due to surface plasmon resonance characteristics to scatter visible light. Accordingly, light that reaches the metal layer 611 may be strongly scattered, and this light conversion efficiency may be improved.

In addition, the first bank unit 610 may further include transparent coating layer 612 disposed on each of the upper and lower portions of the metal layer 611. Accordingly, the transparent coating layer 612 may have an approximately V-shape, similar to the metal layer 611. In addition, the transparent coating layer 612 may include a protruding portion to form the wing portion 600W together with the protruding portion 611-3 of the metal layer 611.

In an embodiment, the transparent coating layer 612 may include ITO. Accordingly, the metal layer 611 may be 1000 Å thick, and each transparent coating layer 612 may be 100 Å thick. The transparent coating layer 612 may ensure better adhesion when the metal layer 611, for example, an Ag layer, is arranged. In addition, because the transparent coating layer 612 is transparent, light reflection of the metal layer 611 may not be affected while strengthening the adhesion to the metal layer 611.

However, the disclosure is not limited thereto. In an embodiment, the metal layer 611 may include Al. At this time, the transparent coating layer 612 may not be disposed on the upper and lower portions of the metal layer 611. Hereinafter, for convenience of explanation, as shown in FIG. 6, the case in which the metal layer 611 includes Ag, and the transparent coating layer 612 is disposed on each of the upper and lower portions of the metal layer 611 is mainly described.

The first bank unit 610 may also further include an insulating layer 613 disposed on the upper portion of the transparent coating layer 612. In other words, the insulating layer 613 may be arranged between the second bank unit 620 to be described below and the metal layer 611 and/or between the second bank unit 620 and the transparent coating layer 612. Accordingly, the insulating layer 613 may have an approximately V-shape, similar to the metal layer 611. In addition, the insulating layer 613 may include a protruding portion to form the wing portion 600W together with the protruding portion 611-3 of the metal layer 611.

In an embodiment, the insulating layer 613 may include an inorganic insulating material, such as silicon nitride.

The second bank unit 620 may be disposed on the upper portion of the first bank unit 610. The second bank unit 620 may be, for example, disposed on the upper portion of the insulating layer 613 and may be arranged to fill the groove GV. Accordingly, the second bank unit 620 may have an approximately T-shape.

In an embodiment, the second bank unit 620 may include a liquid-repellent material that has liquid-repellent characteristics relative to the materials forming the first quantum dot layer 510, the second quantum dot layer 520, and the transmissive layer 530. The liquid-repellent material may include a hydrophobic organic polymer material. For example, the liquid-repellent material may include an organic material containing fluorine (F).

The second bank unit 620 may serve to impart liquid-repellent characteristics such that inks forming the first quantum dot layer 510, the second quantum dot layer 520, and the transmissive layer 530 are not applied on the bank unit 600 and located within the bank openings 600OP during a process of forming the first quantum dot layer 510, the second quantum dot layer 520, and the transmissive layer 530, for example, an inkjet printing process. Because the inks are hydrophilic and the second bank unit 620 is hydrophobic, the second bank unit 620 may prevent the inks from overflowing from the bank opening 600OP where each ink should be located to other adjacent bank openings 600OP. Accordingly, the manufacturing quality of the display apparatus 1 may be improved by preventing mixing between the first quantum dot layer 510, the second quantum dot layer 520, and the transmissive layer 530, which are adjacent to each other, and preventing color mixing between pixels.

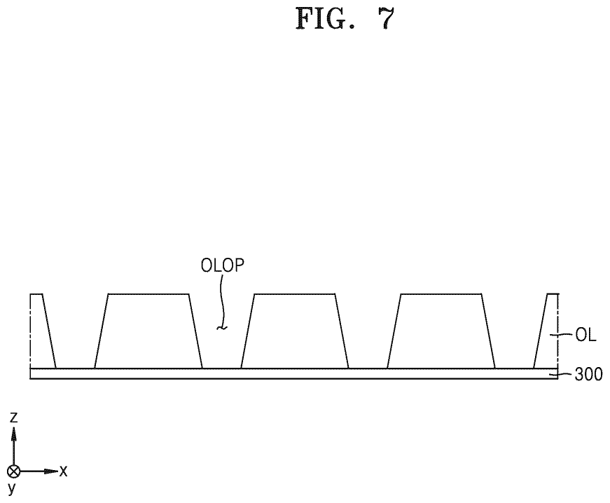

FIGS. 7 to 11 are schematic cross-sectional views illustrating some operations of a method of manufacturing a display apparatus according to an embodiment.

Referring to FIGS. 5 and 7, first, the substrate 100, the circuit layer PCL on the substrate 100, the display element layer DEL on the circuit layer PCL, and the encapsulation layer 300 on the display element layer DEL may be arranged. In FIG. 7, only the encapsulation layer 300 is shown for convenience of explanation.

An organic layer OL may be disposed on the encapsulation layer 300. In an embodiment, the organic layer OL may include polyimide. The organic layer OL may define organic openings OLOP. The organic openings OLOP are spaces for arranging the bank unit 600, which may be arranged adjacent to the pixel defining layer 215. At this time, the organic layer OL may be arranged to be above and overlap the first to third emission areas EA1, EA2, and EA3. In addition, the organic layer OL may be arranged to be above and overlap the first to third light-emitting diodes LED1, LED2, and LED3. In an embodiment, the organic layer OL may have a normal trapezoidal shape.

That is, the organic layer OL may be tapered to have a reducing width in an upward direction away from the encapsulation layer 300. In addition, the organic opening OLOP may have an inverted trapezoidal shape. That is, the organic opening may be a tapered opening to have an increasing width in an upward direction away from the encapsulation layer 300.

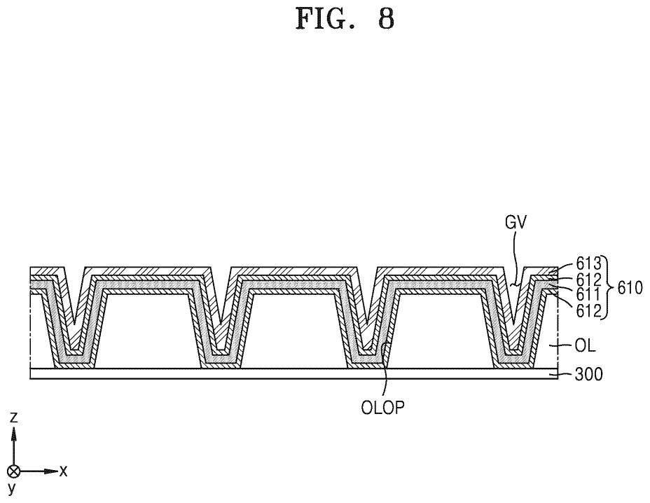

Referring to FIG. 8, the transparent coating layer 612 and the metal layer 611 may be deposited on the organic layer OL and the organic opening OLOP to cover the organic layer OL and the organic opening OLOP. For example, a lower transparent coating layer 612 may be deposited, the metal layer 611 may be deposited on the lower transparent coating layer 612, and an upper transparent coating layer 612 may be deposited again on the metal layer 611. The insulating layer 613 may be deposited on the upper transparent coating layer 612. Accordingly, because the transparent coating layer 612, the metal layer 611, and the insulating layer 613 are deposited along the shapes of the organic layer OL and the organic opening OLOP, which are tapered, the transparent coating layer 612, the metal layer 611, and the insulating layer 613 may have an approximately V-shape within the organic opening OLOP and include the groove GV, as described above. In addition, the transparent coating layer 612, the metal layer 611, and the insulating layer 613 may be said to have an overall concavo-convex structure. In particular, the transparent coating layer 612, the metal layer 611, and the insulating layer 613 may have a concave portion on the organic opening OLOP and may have a convex portion on the organic layer OL.

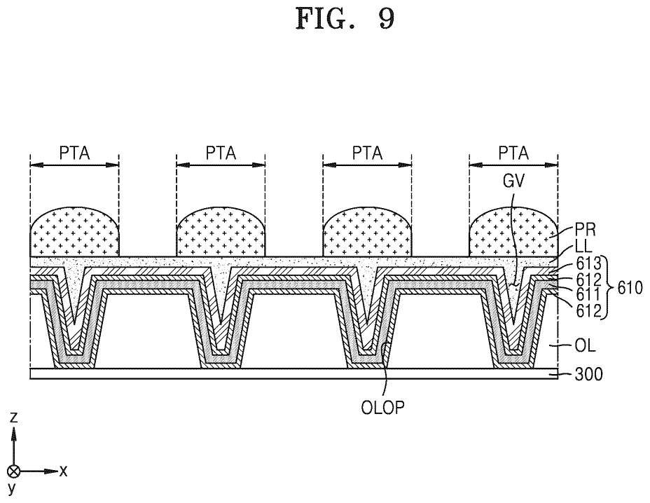

Referring to FIG. 9, a liquid-repellent layer LL may be disposed on the insulating layer 613. The liquid-repellent layer LL may include a liquid-repellent material and may be arranged to fill the groove GV, as described above.

In addition, a photoresist PR may be disposed on the liquid-repellent layer LL. In particular, the photoresist PR may be arranged in a photo area PTA. The photo area PTA is an area where the photoresist PR is arranged, which may also be an area above and overlapping the organic opening OLOP in a plan view. In addition, in an embodiment, the photo area PTA may be formed wider than the width of the organic opening OLOP. That is, the photoresist PR may be arranged to be wider than the width of the organic opening OLOP to cover the organic opening OLOP.

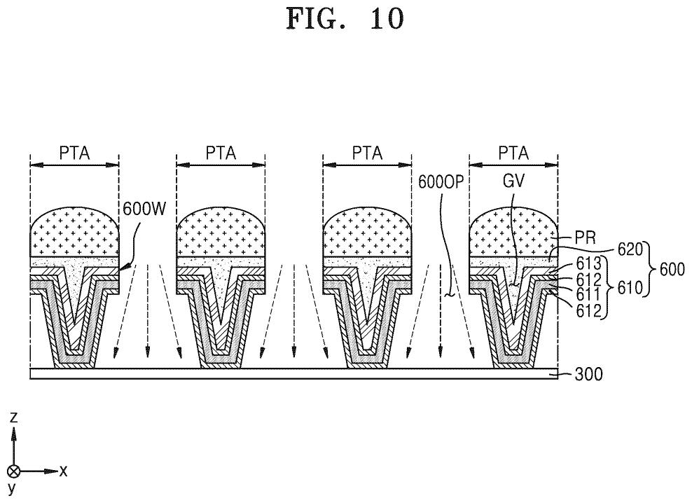

Referring to FIG. 10, the organic layer OL, the transparent coating layer 612, the metal layer 611, the insulating layer 613, and the liquid-repellent layer LL may be etched. In an embodiment, the organic layer OL, the transparent coating layer 612, the metal layer 611, the insulating layer 613, and the liquid-repellent layer LL may be dry-etched. At this time, remaining areas except for the photo area PTA wherein the photoresist PR is arranged may be etched. That is, an area overlapping the organic opening OLOP may not be etched, and the organic layer OL may be etched.

At this time, because the photo area PTA is greater than the width of the organic opening OLOP, the bank unit 600 including the wing portion 600W may be formed. The photo area PTA may be set to be less than the width of the organic opening OLOP by considering the tolerance of a portion to be etched. In addition, an area except the photo area PTA, that is, the organic layer OL, the transparent coating layer 612, the metal layer 611, the insulating layer 613, and the liquid-repellent layer LL, which are disposed on the organic layer OL, may be etched to form the bank opening 600OP.

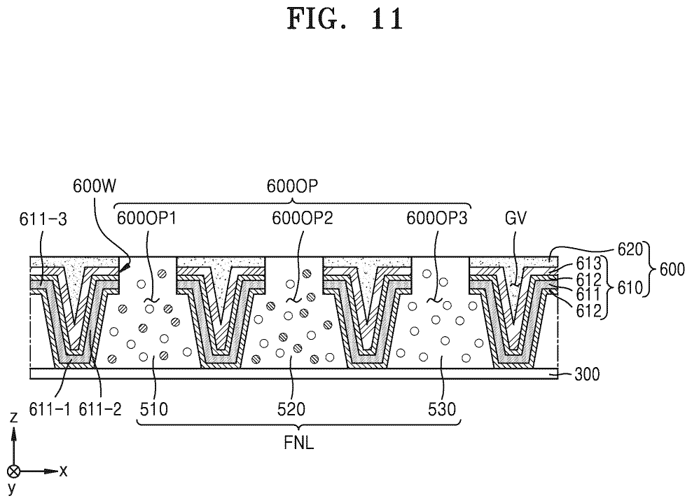

Referring to FIG. 11, the photoresist PR may be removed by a photoresist strip process. In addition, the functional layer FNL may be arranged in the bank opening 600OP. In an embodiment, the functional layer FNL may be arranged through an inkjet printing process.

A method of manufacturing a display apparatus according to an embodiment may form the bank unit 600 having an inverted trapezoidal shape and arrange the metal layer 611 on the outer surface of the bank unit 600 at the same time. Accordingly, light incident on the first quantum dot layer 510, the second quantum dot layer 520, and the transmissive layer 530 may be continuously reflected into the first quantum dot layer 510, the second quantum dot layer 520, and the transmissive layer 530, and thus more color conversion or scattering may occur.

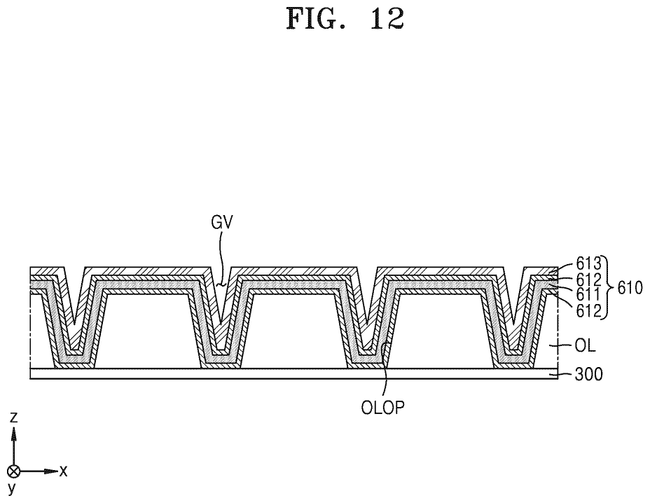

FIGS. 12 to 15 are schematic cross-sectional views illustrating some operations of a method of manufacturing a display apparatus according to an embodiment. Because the method of manufacturing the display apparatus according to an embodiment is similar to the method described above, hereinafter, differences thereof are mainly described.

Referring to FIG. 12, as described above, the transparent coating layer 612, the metal layer 611, and the insulating layer 613 may be disposed on the organic layer OL and the organic opening OLOP.

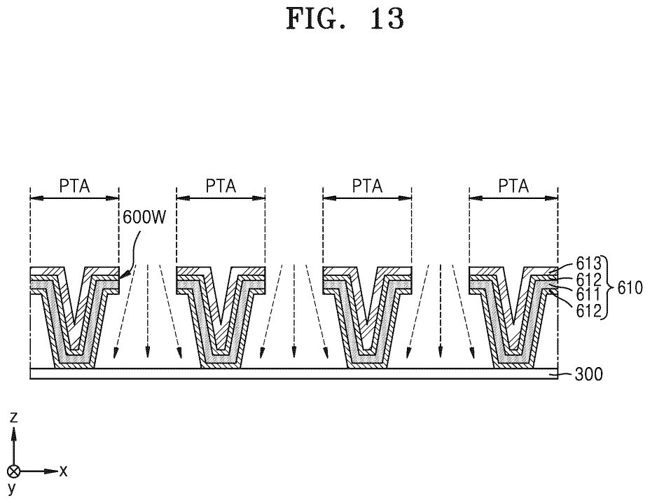

Referring to FIG. 13, remaining areas except the photo area PTA may be etched. That is, an area overlapping the organic opening OLOP may not be etched, and the organic layer OL may be etched. At this time, because the photo area PTA is wider than the width of the organic opening OLOP, the first bank unit 610 including the wing portion 600W may be formed.

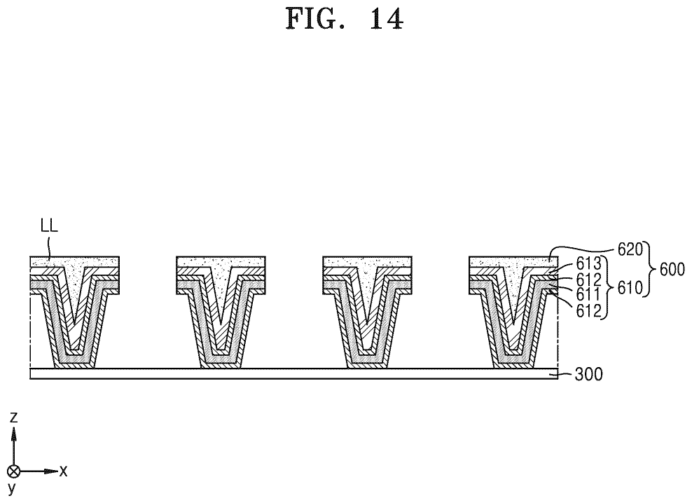

Referring to FIG. 14, the liquid-repellent layer LL may be disposed on the insulating layer 613. In particular, the liquid-repellent layer LL may be arranged to fill the groove GV, and accordingly, the liquid-repellent layer LL may be arranged to have an approximately T-shape. In an embodiment, the liquid-repellent layer LL may be disposed on the first bank unit 610 through an inkjet printing process and may be cured to form the second bank unit 620.

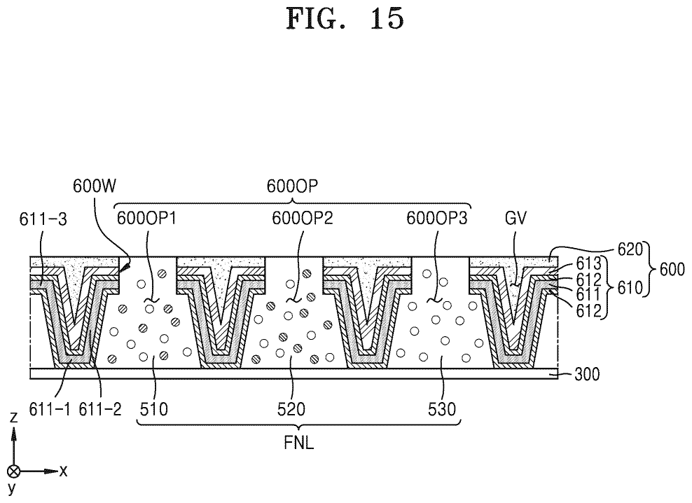

Referring to FIG. 15, the functional layer FNL may be arranged in the bank opening 600OP. In an embodiment, the functional layer FNL may be arranged through an inkjet printing process.

According to an embodiment, a bank portion that may improve light scattering and reflection may be included. Accordingly, color mixing may be prevented, brightness and light conversion efficiency may be improved, and a display apparatus with improved display quality and a method of manufacturing the display apparatus may be implemented.

Effects of the disclosure are not limited to the effects mentioned above, and other effects not mentioned will be clearly understood by one of ordinary in the art from the description of the claims.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a plurality of light-emitting elements configured to emit light;
an encapsulation layer covering the plurality of light-emitting elements;
a bank unit disposed on the encapsulation layer and defining bank openings respectively above the plurality of light-emitting elements; and
a functional layer arranged in each of the bank openings,
wherein the bank unit is tapered to have an increasing width in a first direction away from the encapsulation layer and comprises a wing portion protruding toward the functional layer.

2. The display apparatus of claim 1, wherein the bank unit further comprises:
a first bank unit having a V-shape to have a groove having an increasing width in the first direction at a center of the first bank unit, and
a second bank unit filling the groove of the first bank unit.

3. The display apparatus of claim 2, wherein the first bank unit comprises a metal layer, the metal layer comprising:
a flat portion on the encapsulation layer;
inclined portions respectively arranged on sides of the flat portion and inclined from the flat portion to be farther away from each other in the first direction; and
a protruding portion protruding from each of the inclined portions toward the functional layer.

4. The display apparatus of claim 3, wherein the first bank unit further comprises a transparent coating layer disposed on each of upper and lower portions of the metal layer.

5. The display apparatus of claim 4, wherein the transparent coating layer comprises indium tin oxide (ITO).

6. The display apparatus of claim 3, wherein the first bank unit further comprises an insulating layer between the metal layer and the second bank unit.

7. The display apparatus of claim 3, wherein each of the inclined portions of the metal layer has a thickness at a portion proximal to the flat portion greater than a thickness at a portion distal from the flat portion.

8. The display apparatus of claim 3, wherein the metal layer comprises silver (Ag).

9. The display apparatus of claim 2, wherein the second bank unit comprises a liquid-repellent material having liquid-repellent characteristics.

10. The display apparatus of claim 9, wherein the second bank unit fills the groove and has a T-shape.

11. A method of manufacturing a display apparatus, the method comprising:
arranging an encapsulation layer to cover a plurality of light-emitting elements;
disposing an organic layer on the encapsulation layer;
forming a plurality of organic openings in the organic layer;
arranging a plurality of layers including a metal layer to cover the plurality of organic openings and the organic layer;
forming a bank unit defining a bank opening by etching layers stacked on an upper portion of the encapsulation layer in an area other than a photo area that is above the plurality of organic openings in a plan view; and
arranging a functional layer in the bank opening.

12. The method of claim 11, wherein each of the plurality of organic openings is tapered to have an increasing width in a first direction away from the encapsulation layer.

13. The method of claim 12, wherein the arranging of the plurality of layers comprises arranging the metal layer in a V-shape along a shape of the tapered organic opening to provide a groove having an increasing width in the first direction from a center of the organic opening.

14. The method of claim 13, wherein the arranging of the plurality of layers further comprises arranging a liquid-repellent layer to cover the metal layer and fill the groove.

15. The method of claim 13, wherein the forming of the bank unit comprises etching the plurality of layers and arranging a liquid-repellent layer to fill the groove.

16. The method of claim 13, wherein a width of the photo area is greater than a width of the organic opening, and the forming of the bank unit comprises providing a wing portion protruding toward the bank opening.

17. The method of claim 11, wherein the arranging of the plurality of layers further comprises arranging a transparent coating layer over and under the metal layer.

18. The method of claim 11, wherein the metal layer of the bank unit comprises:
a flat portion on the encapsulation layer;
inclined portions respectively arranged on sides of the flat portion and inclined from the flat portion to be farther away from each other in the first direction; and
a protruding portion protruding from each of the inclined portions toward the bank opening.

19. The method of claim 18, wherein each of the inclined portions of the metal layer has a thickness at a portion proximal to the flat portion greater than a thickness at a portion distal from the flat portion.

20. The method of claim 11, wherein the metal layer comprises silver (Ag).

21. An electronic apparatus including the display apparatus of claim 1.
